(19) United States
(12) Patent Application Publication
(10) Pub. No.: US 2008/0122010 A1
(43) Pub. Date: May 29, 2008

(54) TRANSISTOR HAVING SOURCE/DRAIN REGION ONLY UNDER SIDEWALL SPACER EXCEPT FOR CONTACTS AND METHOD

(75) Inventors: Brent A. Anderson, Jericho, VT (US); Andres Bryant, Burlington, VT (US); William F. Clark, Essex Junction, VT (US); Edward J. Nowak, Essex Junction, VT (US)

Correspondence Address: HOFFMAN, WARNICK & D'ALESSANDRO LLC, 75 STATE ST, 14TH FLOOR, ALBANY, NY, 12207, US

(73) Assignee: INTERNATIONAL BUSINESS MACHINES CORPORATION, Armonk, NY (US)

(21) Appl. No.: 11/555,826

(22) Filed: Nov. 2, 2006

(51) Int. Cl. H01L 29/78; H01L 21/84

(52) U.S. Cl. 257/392; 438/151; 257/E29.255; 257/E21.7

(57) ABSTRACT

A transistor and related method are disclosed. The transistor may include a gate, a sidewall spacer formed along the gate, and a source/drain region positioned only under the sidewall spacer except for a portion at which a contact is positioned. The transistor may be ultra-low power and sub-threshold voltage or near sub-threshold voltage. The transistor may exhibit at least two times reduction in outer fringe capacitance (C_{of}).

### BACKGROUND OF THE INVENTION

1. Technical Field

The invention relates generally to integrated circuits, and more particularly, to a transistor having a source/drain region only under a sidewall spacer except at a portion at which a contact is positioned, and a related method.

2. Background Art

In integrated circuits, outer fringe capacitance (C_{of}) between a gate and associated source/drain regions is a significant component of field effect transistor (FET) capacitance. Outer fringe capacitance is a parasitic capacitance that decreases performance and increases power. The impact of C_{of} is even more significant for sub-threshold voltage (sub-Vₜ) operation where inversion layer capacitance is eliminated. This issue is more important in the case of semiconductor-on-insulator (SOI) FETs for which the source/drain junction capacitance has been eliminated.

There are a number of approaches to reduce C_{of}. In one approach, C_{of} can be reduced by decreasing the gate FET height. However, this does not remove fringe capacitance fields to the source/drain regions. In another approach, C_{of} can be reduced by reducing the size of source/drain regions. In this case, however, series resistance (Rₛ) can increase and degrade FET current drive. This situation can be a problem for typical super-threshold voltage (super-Vₜ) operation. But near-sub threshold voltage (near-sub Vₜ) and sub-Vₜ operation is much less sensitive to Rₛ. Accordingly, it makes sense to reduce the source/drain size of source/drain regions to decrease C_{of} despite consequent increases in Rₛ.

### SUMMARY OF THE INVENTION

A transistor and related method are disclosed. The transistor may include a gate, a sidewall spacer formed along the gate, and a source/drain region positioned only under the sidewall spacer except for a portion at which a contact is positioned. The transistor may be ultra-low power and sub-threshold voltage or near sub-threshold voltage. The transistor may exhibit at least two times reduction in outer fringe capacitance (C_{of}).

A first aspect of the invention provides a transistor comprising: a gate; a sidewall spacer formed along the gate; and a source/drain region positioned only under the sidewall spacer except for a portion at which a contact is positioned.

A second aspect of the invention provides a method of forming a transistor, the method comprising: providing a semiconductor-on-insulator (SOI) substrate; forming active regions in a semiconductor layer of the SOI substrate; forming a gate stack including a cap layer having a first thickness; forming a sidewall spacer along the gate stack; forming a source/drain region including under the sidewall spacer; removing the source/drain region outside of the sidewall spacer except at a portion at which a contact is to be positioned; filling the removed source/drain region with an insulator; and forming contacts.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a cross-sectional view of a transistor according to one embodiment.

FIG. 2 shows a top view of the transistor according to FIG. 1, with a sidewall spacer removed.

FIG. 3 shows part of a method according to one embodiment.

FIG. 4 shows another part of a method according to one embodiment.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

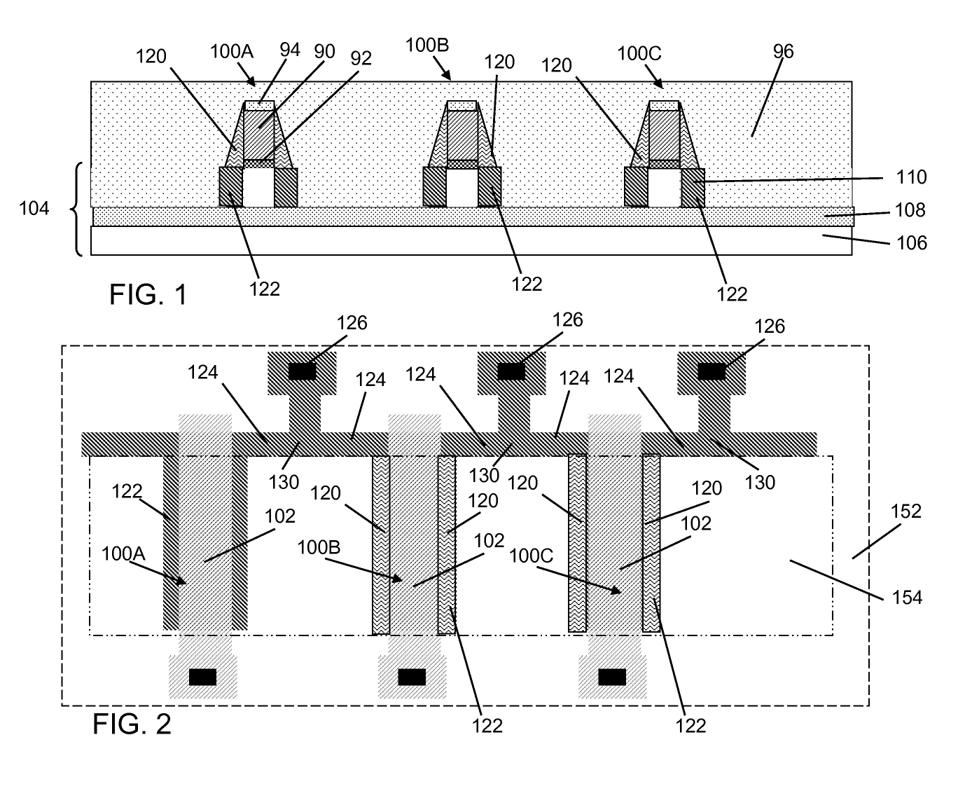

Referring to FIGS. 1 and 2, a transistor(s) 100A, 100B, 100C according to one embodiment is shown. FIG. 1 shows a cross-sectional view and FIG. 2 shows a plan view. In one embodiment, transistors 100A-C each include a field effect transistor (FET) that is ultra-low power and one of sub-threshold voltage (sub-Vₜ) and near sub-threshold voltage (near sub-Vₜ) in operation. In this embodiment, each transistor 100A-C includes a gate 102 on a substrate 104. Gate 102 may include any now known or later developed structure and materials such as a polysilicon 90, a gate dielectric 92 and a cap layer 94 (e.g., silicon nitride or other cap material). Gate dielectric 92 may include but is not limited to: hafnium silicate (HfSi), hafnium oxide (HfO₂), zirconium silicate (ZrSiOx), zirconium oxide (ZrO₂), silicon oxide (SiO₂), silicon nitride (Si₃N₄), silicon oxynitride (SiON), high-k material or any combination of these materials. An interlevel dielectric (ILD) 96 may surround transistors 100A-C. ILD 96 may include but is not limited to: silicon nitride (Si₃N₄), silicon oxide (SiO₂), fluorinated SiO₂ (FSG), hydrogenated silicon oxycarbide (SiCOH), porous SiCOH, boro-phosho-silicate glass (BPSG), etc., or a combination thereof.

In one embodiment, substrate 104 may include a semiconductor-on-insulator (SOI) substrate including a silicon substrate 106, a buried insulator layer 108 (e.g., silicon oxide or any other insulator material), and a semiconductor layer 110 (e.g., silicon, silicon germanium, or any other semiconductor material). Other substrates such as bulk silicon may also be employed. A sidewall spacer 120 is formed along gate 102. A source/drain region 122 is positioned only under sidewall spacer 120 except for a portion 122 (FIG. 2 only) at which a contact 126 (FIG. 2 only) is positioned. Note sidewall spacer 120 is removed from gate 102 of transistor 100A in FIG. 2 so that source/drain region 122 thereof can be viewed. As shown in FIG. 2, portion 124 may include an interconnect 130 to portion 124 of another transistor. As stated above, in one embodiment, transistor 100A-C includes a field effect transistor (FET) that is ultra-low power and one of sub-threshold voltage and near sub-threshold voltage. For this type device, transistor 100A-C may exhibit at least two times reduction in outer fringe capacitance (C_{of}).

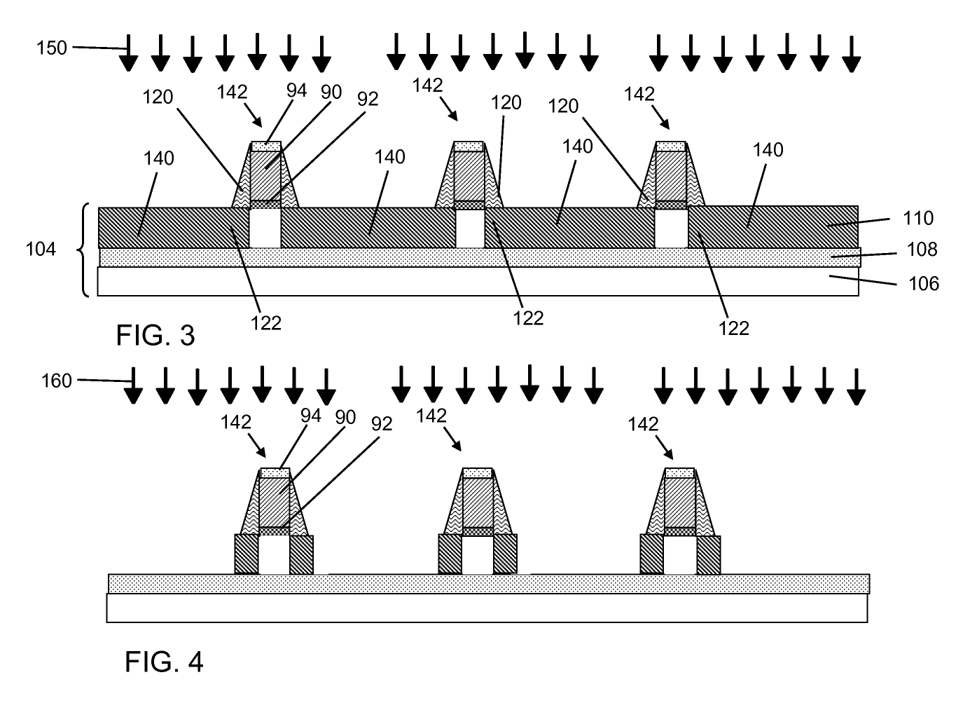

Turning to FIGS. 3-4, one embodiment of a method of forming a transistor(s) 100A-C is illustrated. As shown in FIG. 3, SOI substrate 104 may be provided. FIG. 3 also shows forming active regions 140 (e.g., by implanting boron for an n-type FET) in semiconductor layer 110 of SOI substrate 104. Although not shown, it is understood that active regions 140 may be isolated, e.g., via shallow trench isolations, in areas of the integrated circuit such as where contacts 126 (FIG. 2) are present. Furthermore, although not shown, wells for transistor(s) 100A-C may also be formed at this stage.

Next, as also shown in FIG. 3, a gate stack 142 is formed including, among other things, cap layer 94. Gate stack 142 may be formed using any now known or later developed process. For example, gate dielectric 92 may be formed by thermal oxidation. Gate polysilicon 90 and cap layer 94 may be deposited, and then gate dielectric 92, gate polysilicon 90 and cap layer 94 may be etched using a patterned photoresist (not shown). Cap layer 94 has a first thickness that is thicker than sidewall spacer 122 to be formed thereafter.

Sidewall spacer 120 is then formed along gate stack 142 in any now known or later developed manner, e.g., deposition of silicon nitride and etching. A thickness of sidewall spacer 122, as will be described herein, determines a size of source/drain regions 122.

FIG. 3 also shows forming source/drain region 122 including under sidewall spacer 120, e.g., by implanting 150 a dopant such as arsenic (As) for an NFET.

FIG. 4 shows removing source/drain region 122 (FIG. 3) outside of sidewall spacer 120 except at a portion 124 (FIG. 2) at which contact 126 (FIG. 2) is to be positioned. The removing process may include forming a barrier layer 152 (FIG. 2 between single dashed line and double dashed line) to protect connecting regions of SOI substrate 104, patterning barrier layer 152 to expose the source/drain region 154 (FIG. 2 inside of double dashed line) to be removed, and etching 160 (FIG. 4). Barrier layer 152 may include a number of layers such as a silicon oxide layer and a silicon nitride layer. As shown in FIG. 4, cap layer 94 being thicker than sidewall spacer 120 ensures gate stack 142 is protected during etching 160.

Returning to FIG. 1, the removed source/drain region is then filled with an insulator, e.g., ILD 96. ILD 96 may be planarized, e.g., using chemical mechanical polishing (CMP). Subsequent processing may include any now known or later developed techniques to form contacts 126 (FIG. 2). Other structures such as wiring (not shown) can also be formed.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A transistor comprising:
a gate;
a sidewall spacer formed along the gate; and
a source/drain region positioned only under the sidewall spacer except for a portion at which a contact is positioned.

2. The transistor of claim 1, wherein the portion includes an interconnect to the portion of another transistor.

3. The transistor of claim 1, wherein the transistor includes a field effect transistor that is ultra-low power and one of sub-threshold voltage and near sub-threshold voltage.

4. A method of forming a transistor, the method comprising:
providing a semiconductor-on-insulator (SOI) substrate;
forming active regions in a semiconductor layer of the SOI substrate;
forming a gate stack including a cap layer having a first thickness;
forming a sidewall spacer along the gate stack;
forming a source/drain region including under the sidewall spacer;
removing the source/drain region outside of the sidewall spacer except at a portion at which a contact is to be positioned;
filling the removed source/drain region with an insulator; and
forming contacts.

5. The method of claim 4, wherein the removing includes forming a barrier layer to protect connecting regions of the SOI substrate, patterning the barrier layer to expose the source/drain region to be removed, and etching.
